(19) United States
(12) Patent Application Publication
(10) Pub. No.: US 2012/0068755 A1
(43) Pub. Date: Mar. 22, 2012

(54) LEVEL SHIFTER

(75) Inventors: Mitsuo Yamamoto, Kanagawa-ken (JP); Akira Takiba, Kanagawa-ken (JP)

(73) Assignee: KABUSHIKI KAISHA TOSHIBA, Tokyo (JP)

(21) Appl. No.: 13/052,324

(22) Filed: Mar. 21, 2011

(30) Foreign Application Priority Data
Sep. 16, 2010 (JP) 2010-208298

(51) Int. Cl. H03L 5/00

(52) U.S. Cl. 327/333

(57) ABSTRACT

According to one embodiment, a level shifter includes a high-side switch and a low-side switch. The high-side switch is connected between a high-potential power supply and a connection point and turned on in accordance with an input signal. The low-side switch is connected between the connection point and a low-potential power supply and turned on in accordance with an input signal. A ratio between ON resistance of the high-side switch and ON resistance of the low-side switch is set in accordance with a signal difference between an output signal and the input signal. The output signal is outputted to the connection point.

### CROSS-REFERENCE TO RELATED APPLICATIONS

This application is based upon and claims the benefit of priority from the prior Japanese Patent Application No. 2010-208298, filed on Sep. 16, 2010; the entire contents of which are incorporated herein by reference.

### FIELD

Embodiments described herein relate generally to a level shifter.

### BACKGROUND

With a trend to lower power consumption and higher functions of equipment, integrated circuits such as CPU have lower voltages and more power sources. On the other hand, in a system having been used hitherto and a system handling analog signals, a high voltage is rather needed than an integrated circuit in some cases.

As described above, if systems operating at different power voltages are mixed, a level shifter that transmits signals between the systems is required. Also, with the trend to speed-up of the equipment, propagation delay caused by a level shifter needs to be reduced.

However, an optimal transistor size ratio that can minimize the propagation delay time differs depending on a level difference between input and output. Thus, in such a configuration that switching to a plurality of power voltages is possible, optimization of the propagation delay time is difficult.

### BRIEF DESCRIPTION OF THE DRAWINGS

FIG. 1 is a circuit diagram illustrating the configuration of a level shifter according to a first embodiment;

FIG. 2 is a characteristic diagram indicating dependency of the propagation delay time on the transistor size ratio;

FIG. 3 is a circuit diagram illustrating the configuration of a level shifter according to a second embodiment;

FIG. 4 is a circuit diagram illustrating the configuration of a level shifter according to a third embodiment;

FIG. 5 is a circuit diagram illustrating the configuration of a level shifter according to a fourth embodiment;

FIG. 6 is a circuit diagram illustrating the configuration of a level shifter according to a fifth embodiment;

FIG. 7 is a circuit diagram illustrating the configuration of a level shifter according to a sixth embodiment;

FIG. 8 is a characteristic diagram indicating dependency of the propagation delay time of the level shifter illustrated in FIG. 7 on the transistor size ratio;

FIG. 9 is a circuit diagram illustrating the configuration of a level shifter according to a seventh embodiment;

FIG. 10 is a circuit diagram illustrating the configuration of a level shifter according to an eighth embodiment;

FIG. 11 is a circuit diagram illustrating the configuration of a level shifter according to a ninth embodiment; and

FIG. 12 is a circuit diagram illustrating the configuration of a level shifter according to a tenth embodiment.

### DETAILED DESCRIPTION

In general, according to one embodiment, a level shifter includes a high-side switch and a low-side switch. The high-side switch is connected between a high-potential power supply and a connection point and turned on in accordance with an input signal. The low-side switch is connected between the connection point and a low-potential power supply and turned on in accordance with an input signal. A ratio between ON resistance of the high-side switch and ON resistance of the low-side switch is set in accordance with a signal difference between an output signal and the input signal. The output signal is outputted to the connection point.

Various embodiments will be described hereinafter with reference to the accompanying drawings. In the specification of the application and the drawings, components similar to those described in regard to a drawing thereinabove are marked with like reference numerals, and a detailed description is omitted as appropriate.

### First Embodiment

FIG. 1 is a circuit diagram illustrating the configuration of a level shifter according to a first embodiment.

As illustrated in FIG. 1, in a level shifter 1, a high-side switch 2 and a low-side switch 3 are connected in series between a high-potential power line (high-potential power supply) 4 and a low-potential power line (low-potential power supply) 5. An output line 6 is connected to a connection point 7b between the high-side switch 2 and the low-side switch 3.

Input lines 8a and 8b are connected to the low-side switch 3, and input signals Ina and Inb are inputted into the low-side switch 3. Here, the input signals Ina and Inb are differential signals having a high level at a potential V1 and a low level at 0V based on the potential of the low-potential power line 5. The input signal Inb is a signal obtained by inverting the input signal Ina. The input signal Ina is inverted by a NOT circuit 10 to which power with the potential V1 is supplied from the power line 9.

The low-side switch 3 is tuned on or off in accordance with the input signals Ina and Inb. The high-side switch 2 is turned on or off in accordance with the state of the low-side switch 3. The high-side switch 2 and the low-side switch 3 are turned on exclusively. Thus, the output line 6 is electrically connected to the high-potential power line 4 or the low-potential power line 5 in accordance with the input signals Ina and Inb.

An output signal Out of the output line 6 is a signal having a high level at a potential V2 and a low level at 0V based on the potential of the low-potential power line 5. Here, the potential V2 is the potential V2 of the high-potential power line 4 and is set to a value of the high-level potential V1 or more of the input signals Ina and Inb. Also, in the level shifter 1, there are two cases, that is, one case in which the potential V2=V2A and the other case in which the potential V2=V2B. However, V2A≧V2B>0.

The level shifter 1 converts the input signals Ina and Inb with the high-level potential V1 to the output signal Out with the high-level potential V2.

Also, as will be described later, ON resistance Rl of the low-side switch 3 between the connection point 7b and the low-potential power line 5 is set in accordance with an level difference (signal difference between input and output signals) between the input signals Ina and Inb and the output signal Out, V2−V1=V2A−V1, V2B−V1.

Therefore, a ratio Rh/Rl between ON resistance Rh of the high-side switch 2 between the high-potential power line 4 and the connection point 7b and the ON resistance Rl of the low-side switch 3 between the connection point 7b and the low-potential power line 5 is set in accordance with the level difference V2−V1.

The high-side switch 2 is constituted by a differential circuit of a pair of output transistors P1 and P2. Each of the output transistors P1 and P2 is constituted by a p-type channel MOSFET (hereinafter referred to as PMOS), and the respective back gates are connected to the high-potential power line 4.

Each source of the output transistors P1 and P2 is connected to the high-potential power line 4. A gate of the output transistor P1 is connected to a drain of the output transistor P2. A gate of the output transistor P2 is connected to a drain of the output transistor P1. The output transistors P1 and P2 are cross-coupled.

The output transistors P1 and P2 are differential circuits and are exclusively turned on.

The output line 6 is connected to the gate of the output transistor P2 and the drain of the output transistor P1 via the connection point 7b.

When the output transistor P1 is ON and the output transistor P2 is OFF, the high-side switch 2 is ON. At this time, the output line 6 is electrically connected to the high-potential power line 4 via the connection point 7b. Also, when the output transistor P1 is OFF and the output transistor P2 is ON, the high-side switch 2 is OFF. At this time, the connection between the output line 6 and the high-potential power line 4 is shut off.

The low-side switch 3 is constituted by a differential circuit of a pair of input transistors N1 and N2, a pair of input transistors N3 and N4, and a pair of serial transistors N5 and N6. Each transistor is constituted by an n-type channel MOSFET (hereinafter referred to as NMOS), and the respective back gates are connected to the low-potential power line 5.

The input transistor N1 is connected between the high-side switch 2 and the low-potential power line 5. The input transistor N3 and the serial transistor N5 are connected in series between the high-side switch 2 and the low-potential power line 5. The input transistor N3 and the serial transistor N5 are connected in parallel to the input transistor N1.

Similarly, the input transistor N2 is connected between the high-side switch 2 and the low-potential power line 5. The input transistor N4 and the serial transistor N6 are connected in series between the high-side switch 2 and the low-potential power line 5. The input transistor N4 and the serial transistor N6 are connected in parallel to the input transistor N2.

In more detail, a drain of the input transistor N1 is connected to the drain of the output transistor P1 of the high-side switch 2 via the connection point 7b. A source of the input transistor N1 is connected to the low-potential power line 5.

A drain of the serial transistor N5 is connected to the drain of the output transistor P1 of the high-side switch 2 via the connection point 7b. A source of the serial transistor N5 is connected to a drain of the input transistor N3. A source of the input transistor N3 is connected to the low-potential power line 5.

A gate of the input transistor N1 and a gate of the input transistor N3 are connected to the input line 8b. Into the gate of the input transistor N1 and the gate of the input transistor N3, the input signal Inb is inputted.

A gate of the serial transistor N5 is connected to a signal line 11, and into the gate of the serial transistor N5, a selection signal Se1 is inputted. The selection signal Se1 is set at a high level or a low level in accordance with the level difference V2−V1 between the input signal Inb and the output single Out.

When the level difference V2−V1 is a first level difference V2A−V1, the selection signal Se1 is at a high level. If the level difference V2−V1 is a second level difference V2B−V1, which is smaller than the first level difference V2A−V1, the selection signal Se1 is at a low level.

Similarly, a drain of the input transistor N2 is connected to the drain of the output transistor P2 of the high-side switch 2. A source of the input transistor N2 is connected to the low-potential power line 5.

A drain of the serial transistor N6 is connected to the drain of the output transistor P2 of the high-side switch 2. A source of the serial transistor N6 is connected to a drain of the input transistor N4. A source of the input transistor N4 is connected to the low-potential power line 5.

A gate of the input transistor N2 and a gate of the input transistor N4 are connected to the input line 8a. Into the gate of the input transistor N2 and the gate of the input transistor N4, the input signal Ina is inputted. A gate of the serial transistor N6 is connected to the signal line 11. To the gate of the serial transistor N6, the selection signal Se1 is supplied.

Subsequently, an operation of the level shifter 1 will be described.

The input transistors N1 and N2 are exclusively turned on by input of the input signals Inb and Ina, respectively. The input transistor N1 is turned on when the input signal Inb is at a high-level and is turned off when the signal is at a low level. The input transistor N2 is turned on when the input signal Ina is at a high level and is turned off when the signal is at a low level.

The input transistors N3 and N4 are also exclusively turned on by input of the input signals Inb and Ina, respectively. The input transistor N3 is turned on when the input signal Inb is at a high-level and is turned off when the signal is at a low level. The input transistor N4 is turned on when the input signal Ina is at a high-level and is turned off when the signal is at a low level.

If the level difference V2−V1 is the first level difference V2A−V1, the selection signal Se1 is at a high level, and thus, the gates of the serial transistors N5 and N6 rise to high levels. The serial transistors N5 and N6 are turned on.

In the low-side switch 3, the input transistor N1 is connected between the output line 6 and the low-potential power line 5, and the input transistor N3 and the serial transistor N5 are connected in parallel to the input transistor N1.

Also, between the drain of the output transistor P2 of the high-side switch 2 and the low-potential power line 5, the input transistor N2 is connected, and the input transistor N4 and the serial transistor N6 are connected in parallel to the input transistor N2.

Therefore, the ON resistance of the low-side switch 3 is expressed as R(N1)×(R(N3)+R(N5))/(R(N1)+R(N3)+R(N5)). Here, R(N1), R(N3), and R(N5) are ON resistances of the input transistors N1 and N3 and the serial transistor N5, respectively.

Also, if the level difference V2−V1 is the second level difference V2B−V1, which is smaller than the first level difference V2A−V1, the gates of the serial transistors N5 and N6 fall to the low levels. The serial transistors N5 and N6 are turned off.

In the low-side switch 3, the input transistor N1 is connected between the output line 6 and the low-potential power line 5. Also, to the drain of the output transistor P2 of the high-side switch 2, the drain of the input transistor N2 is connected.

Therefore, the ON resistance of the low-side switch becomes R(N1).

As described above, the ON resistance of the low-side switch 3 when the level difference V2−V1 is the first level difference V2A−V1 is set smaller than the ON resistance at the second level difference V2B−V1.

If the input signal Inb changes from a high level to a low level, the input transistors N1 and N3 are turned off. The low-side switch 3 between the output line 6 and the low-potential power line 5 is brought into the OFF state. At this time, the input transistors N2 and N4 are ON, and the gate of the output transistor P1 of the high-side switch 2 falls to the low level. The output transistor P1 is turned on, and the high-side switch 2 is brought into the ON state.

The output line 6 is electrically connected to the high-potential power line 4 via the connection point 7b and the output transistor P1. The output signal Out of the output line 6 rises from a low level to a high level and rises to the potential V2 of the high-potential power line 4. The larger the current supply capacity of the output transistor P1 is or the smaller the ON resistance is, the shorter the propagation delay time tpdh at the rise of the output signal Out becomes.

If the input signal Inb changes from a low level to a high level, the input transistors N1 and N3 are turned on. The low-side switch 3 between the output line 6 and the low-potential power line 5 is brought into the on state. The gate of the output transistor P2 of the high-side switch 2 falls to the low level. The output transistor P2 is turned on, and the gate of the output transistor P1 rises to the high level. The output transistor P1 is turned off. At this time, the input transistors N2 and N4 are off, since the input signal Ina changes to the low level.

The output line 6 is electrically connected to the low-potential power line 5 via the connection point 7b and the low-side switch 3. The output signal Out of the output line 6 falls from a high level to a low level and lowers to the potential 0V of the low-potential power line 5. The larger the current supply capacity of the low-side switch 3 is or the smaller the ON resistance is, the shorter the propagation delay time tpdl at the fall of the output signal Out becomes.

Propagation delay time tpd of the level shifter 1 is defined as an arithmetic average tpd=(tpdh+tpdl)/2 of the above propagation delay times tpdh and tpdl.

Therefore, by setting a ratio between the current supply capacity of the high-side switch 2 and the current supply capacity of the low-side switch 3 at an optimal value, the propagation delay time tpd is minimized. Also, by setting a ratio between the ON resistance of the high-side switch 2 and the ON resistance of the low-side switch 3 at an optimal value, the propagation delay time tpd is minimized.

The optimal value relating to the current supply capacity or the ON resistance of the high-side switch 2 and the low-side switch 3 depends on an element parameter of each transistor of the level shifter 1. It also depends on the level difference V2−V1.

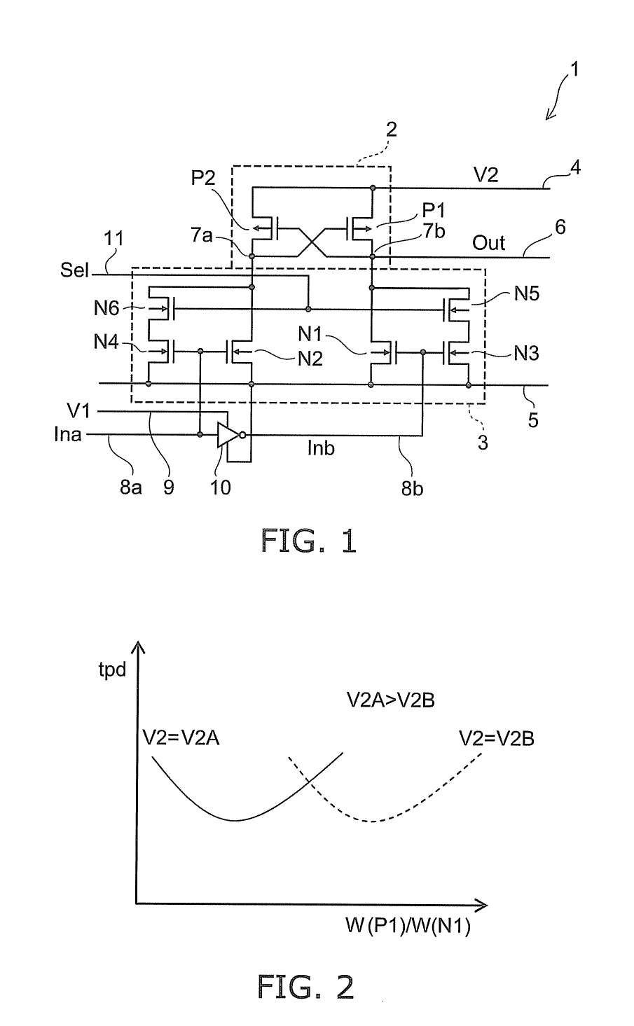

FIG. 2 is a characteristic diagram indicating dependency of the propagation delay time on the transistor size ratio.

In FIG. 2, the horizontal axis indicates the transistor size ratio W(P1)/W(N1), while the vertical axis indicates the propagation delay time tpd, and dependency in each of the cases of the potential V2 of the high-potential power line 4=V2A and V2B is schematically indicated. Each of the cases of the potential V2 of the high-potential power line 4=V2A and V2B corresponds to the case in which the level difference V2−V1 is the first level difference V2A−V1 and the case of the second level difference V2B−V1, respectively. Also, the selection signal Se1 is at a low level, which corresponds to the case in which there is no input transistor N3 or the serial transistor N5.

Here, the transistor size ratio W(P1)/W(N1) is a ratio between a channel width W(P1) of the output transistor P1 of the high-side switch 2 and the channel width W(N1) of the input transistor N1 of the low-side switch 3. Also, a ratio W(P2)/W(N2) between the channel width W(P2) of the output transistor P2 and the channel width W(N2) of the input transistor N2 is equal to the transistor size ratio W(P1)/W(N1). Moreover, the channel lengths of the transistors P1, P2, N1 and N2 are equal.

The current supply capacity of the transistor is in proportion to the channel width thereof. Also, the ON resistance of the transistor is in inverse proportion to the channel width.

Thus, in FIG. 2, the ratio of the current supply capacities of the transistors is expressed as the transistor size ratio W(P1)/W(N1).

As illustrated in FIG. 2, the transistor size ratio W(P1)/W(N1) at which the propagation delay time tpd is the shortest is different depending on the level difference V2−V1. The optimal value of the transistor size ratio W(P1)/W(N1) at the first level difference V2A−V1 is smaller than the optimal value at the second level difference V2B−V1.

Therefore, the ratio of the current supply capacities at the first level difference V2A−V1 needs to be smaller than that at the second level difference V2B−V1. If expressed by the ON resistance of the transistor, the ratio Rh/Rl between the ON resistance Rh of the high-side switch 2 at the first level difference V2A−V1 and the ON resistance Rl of the low-side switch 3 needs to be larger than that at the second level difference V2B−V1.

As described above, if there is no input transistor N3 or N4 or the serial transistor N5 or N6, by switching the potential V2 of the high-potential power line 4, the optimal value of the transistor size ratio W(P1)/W(N1) is changed. Thus, the transistor size ratio W(P1)/W(N1) is set to an optimal value to one value of the level difference V2−V1. Therefore, since the transistor size ratio W(P1)/W(N1) is not an optimal value depending on the potential V2 to be supplied, the circuit is operated in a state in which the propagation delay time tpd is not the shortest.

On the other hand, in the level shifter 1, the ON resistance when the level difference V2−V1 is the first level difference V2A−V1 is set smaller than the ON resistance at the second level difference V2B−V1. Thus, the current supply capacity of the low-side switch 3 at the first level difference V2A−V1 can be made larger than the current supply capacity at the second level difference V2B−V1.

Therefore, in the level shifter 1, even if the potential V2 of the high-potential power line 4 is switched to the potentials V2A and V2B, the transistor size ratio can be equivalently set to an optimal value with respect to the respective potentials. According to the level shifter 1, the propagation delay time tpd can be optimized with respect to a plurality of power voltages.

In the level shifter 1, the potential V2 of the high-potential power line 4 is switched to the potentials V2A and V2B. However, the level difference V2−V1 may be changed by switching the high-level potential V1 of the input signals Ina and Inb.

Also, in the level shifter 1, the configuration using the pair of input transistors N3 and N4 and the pair of serial transistors N5 and N6 connected in parallel to the pair of input transistors N1 and N2 is illustrated. However, the arbitrary number of pairs of the input transistors and serial transistors may be used.

Also, in the level shifter 1, the pair of serial transistors N5 and N6 are on the high-potential side, while the pair of input transistors N3 and N4 and the pair of serial transistors N5 and N6 are connected in series, respectively. However, the pair of serial transistors N5 and N6 may be connected to the low-potential side.

Also, since the level shifter 1 is constituted by a differential circuit, there are two connection points between the high-side switch 2 and the low-side switch 3, that is, the connection points 7a and 7b, and signals inverted from each other are outputted, respectively. In the level shifter 1, to the connection point 7b between the output transistor P1 of the high-side switch 2 and the input transistor N1 of the low-side switch 3, and the input transistor N3 and the serial transistor N5, the output line 6 is connected. However, depending on the logic of the input signals Inb and Inb and the output signal Out, the output line 6 may be connected to the connection point 7a.

Also, in the level shifter 1, the configuration in which the input signal Ina is inverted in the NOT 10 so as to generate the input signal Inb is illustrated. However, the differential signals of the input signals Ina and Inb may be inputted into the level shifter 1 without using the NOT 10.

### Second Embodiment

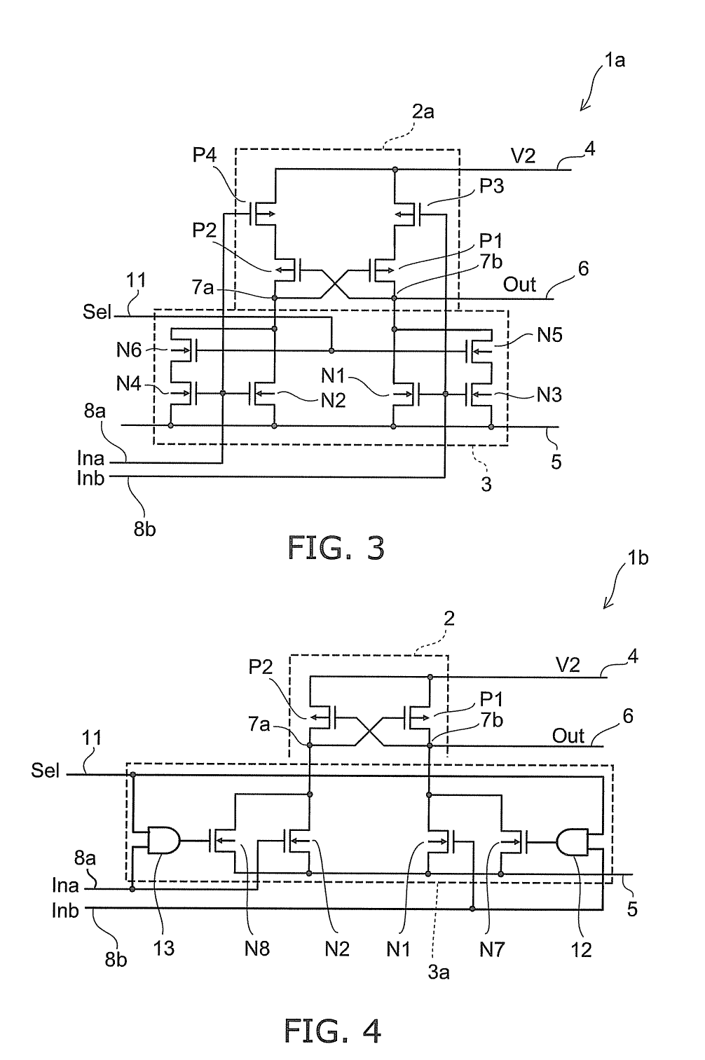

FIG. 3 is a circuit diagram illustrating the configuration of a level shifter according to a second embodiment.

As illustrated in FIG. 3, a level shifter 1a has a configuration in which the high-side switch 2 in the level shifter 1 illustrated in FIG. 1 is replaced by a high-side switch 2a.

The high-side switch 2a has a configuration in which a pair of PMOS P3 and P4 are added to the high-side switch 2. The pair of output transistors P1 and P2 are similar to the high-side switch 2.

The pair of PMOS P3 and P4 are connected in series to the pair of output transistors P1 and P2, respectively.

Sources of the pair of PMOS P3 and P4 are connected to the high-potential power line 4, respectively. A drain of the PMOS P3 is connected to the source of the output transistor P1. A gate of the PMOS P3 is connected to the input line 8b. Into the gate of the PMOS P3, the input signal Inb is inputted.

A drain of the PMOS P4 is connected to the source of the output transistor P2. A gate of the PMOS P4 is connected to the input line 8a. Into the gate of the PMOS P4, the input signal Ina is inputted. The input signals Ina and Inb are differential signals, and the input signal Inb may be generated by inverting Ina in the NOT 10 as in the level shifter 1 illustrated in FIG. 1.

In the level shifter 1a, the low-side switch 3 is similar to that of the level shifter 1, and even if the potential V2 of the high-potential power line 4 is switched to the potential V2A and V2B, the transistor size ratio can be equivalently set to an optimal value with respect to the respective potentials.

Thus, according to the level shifter 1a, the propagation delay time tpd can be optimized to the plurality of power voltages.

Also, since the input signals Ina and Inb are inputted into the high-side switch 2a, the propagation delay time tpd can be shortened.

In the level shifter 1a, the potential V2 of the high-potential power line 4 is switched to the potential V2A and V2B. However, the level difference V2−V1 may be changed by switching the high-level potential V1 of the input signals Ina and Inb.

### Third Embodiment

FIG. 4 is a circuit diagram illustrating the configuration of a level shifter according to a third embodiment.

As illustrated in FIG. 4, a level shifter 1b has a configuration in which the low-side switch 3 in the level shifter 1 illustrated in FIG. 1 is replaced by a low-side switch 3a. The high-side switch 2 is similar to that in the level shifter 1.

The low-side switch 3a has a configuration in which the pair of input transistors N3 and N4 of the low-side switch 3 and the pair of serial transistors N5 and N6 are replaced by a pair of input transistors N7 and N8 and a pair of AND circuits 12 and 13. The input transistors N7 and N8 are constituted by NMOS, respectively. Also, the pair of input transistors N1 and N2 are similar to those in the low-side switch 3.

The pair of input transistors N7 and N8 are connected between the high-side switch 2 and the low-potential power line 5, respectively. A drain of the input transistor N7 is connected to the drain of the output transistor P1 of the high-side switch 2 via the connection point 7b. A source of the input transistor N7 is connected to the low-potential power line 5. A logical product of the selection signal Se1 and the input signal Inb is generated in the AND 12 and inputted to the gate of the input transistor N7.

Similarly, a drain of the input transistor N8 is connected to the drain of the output transistor P2 of the high-side switch 2 via the connection point 7a. A source of the input transistor N8 is connected to the low-potential power line 5. A logical product of the selection signal Se1 and the input signal Ina is generated at the AND 13 and inputted to the gate of the input transistor N8. The input signals Ina and Inb are differential signals and as in the level shifter 1 illustrated in FIG. 1, the input signal Inb may be generated by inverting the Ina at the NOT 10.

As described above, if the level difference V2−V1 is the first level difference V2A−V1, the selection signal Se1 is at a high level. If the level difference V2−V1 is the second level difference V2B−V1, which is smaller than the first level difference V2A−V1, the selection signal Se1 is at a low level.

Therefore, when the level difference is the first level difference V2A−V1, into each gate of the input transistors N7 and N8, the input signals Inb and Ina are inputted, respectively. The input signals Ina and Inb are differential signals and as in the level shifter 1 illustrated in FIG. 1, the input signal Inb may be generated by inverting the Ina at the NOT 10.

In the low-side switch 3a, the input transistor N1 and the input transistor N7 are connected in parallel between the output line 6 and the low-potential power line 5.

Also, between the drain of the output transistor P2 of the high-side switch 2 and the low-potential power line 5, the input transistor N2 and the input transistor N7 are connected in parallel.

Therefore, the ON resistance of the low-side switch 3a is R(N1)×R(N7)/(R(N1)+R(N7)). Here, R(N1) and R(N7) are ON resistances of the input transistors N1 and N7, respectively.

Also, if the level difference is the second level difference V2B−V1, each of the gates of the input transistors N7 and N8 falls to a low level. The input transistors N7 and N8 are turned off.

In the low-side switch 3a, the input transistor N1 is connected between the output line 6 and the low-potential power line 5. Also, to the drain of the output transistor P2 of the high-side switch 2, the drain of the input transistor N2 is connected.

Therefore, the ON resistance of the low-side switch 3a becomes R(N1).

As described above, the ON resistance of the low-side switch 3 when the level difference V2−V1 is the first level difference V2A−V1 is set smaller than the ON resistance at the second level difference V2B−V1.

In the level shifter 1b, the high-side switch 2 is similar to the level shifter 1, and even if the potential V2 of the high-potential power line 4 is switched to potentials V2A and V2B, the transistor size ratio can be equivalently set to an optimal value with respect to the respective potentials.

Thus, according to the level shifter 1b, the propagation delay time tpd can be optimized to the plurality of power voltages.

Also, in the low-side switch 3a, since there is no serial transistor N5 or N6, the propagation delay time tpd can be shortened.

In the level shifter 1b, the potential V2 of the high-potential power line 4 is switched to the potential V2A and V2B. However, the level difference V2−V1 may be changed by switching the high-level potential V1 of the input signals Ina and Inb.

Also, in the level shifter 1b, the configuration using the pair of input transistors N3 and N4 and the pair of ANDs 13 and 14 connected in parallel to the pair of input transistors N1 and N2 is illustrated. However, the arbitrary number of pairs of the input transistors and ANDs may be used.

### Fourth Embodiment

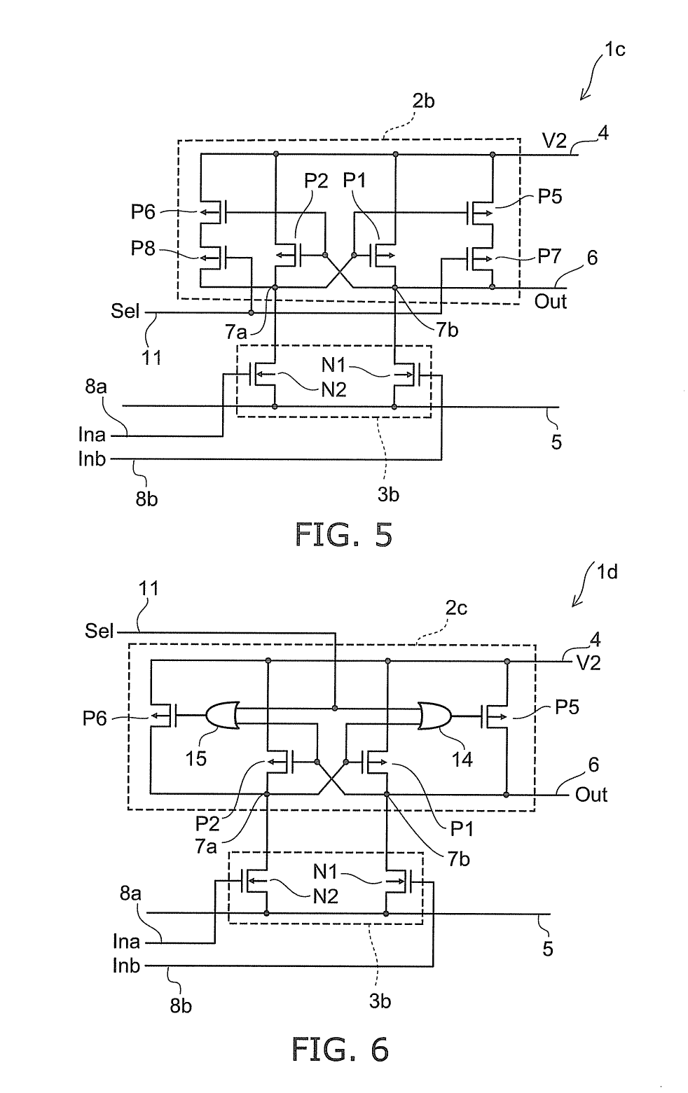

FIG. 5 is a circuit diagram illustrating the configuration of a level shifter according to a fourth embodiment.

As illustrated in FIG. 5, a level shifter 1c has a configuration in which the high-side switch 2 and the low-side switch 3 in the level shifter 1 illustrated in FIG. 1 are replaced by a high-side switch 2b and a low-side switch 3b, respectively. In the level shifter 1c, the ON resistance Rh of the high-side switch 2b is changed in accordance with the selection signal Se1.

The low-side switch 3c has a configuration without the pair of input transistors N3 and N4 and the pair of serial transistors N5 and N6 in the low-side switch 3. The pair of input transistors N1 and N2 are similar to those of the low-side switch 3.

The high-side switch 2b has a configuration in which a pair of output transistors P5 and P6 and a pair of serial switches P7 and P8 are added to the high-side switch 2. Each of the transistors P5 and P6 and the serial switches P7 and P8 is constituted by PMOS. The output transistors P1 and P2 are similar to those of the high-side switch 2.

The pair of output transistors P5 and P6 are connected to the high-potential power line 4. The pair of serial switches P7 and P9 are connected in series to the output transistors P5 and P6, respectively. The output transistor P5 and the serial switch P7 are connected in series to the both ends of the output transistor P1. Similarly, the output transistor P6 and the serial switch P8 are connected in series to the both ends of the output transistor P2.

In more detail, a source, a drain and a gate of the output transistor P5 are connected to the high-potential power line 4, a source of the serial switch P7 and the gate of the output transistor P1, respectively. A drain of the serial switch P7 is connected to the drain of the output transistor P1. Into a gate of the serial switch P7, the selection signal Se1 is inputted.

Similarly, a source, a drain and a gate of the output transistor P6 are connected to the high-potential power line 4, a source of the serial switch P8, and the gate of the output transistor P2, respectively. A drain of the serial switch P8 is connected to the drain of the output transistor P2. Into a gate of the serial switch P8, the selection signal Se1 is inputted.

As described above, if the level difference V2−V1 is the first level difference V2A−V1, the selection signal Se1 is at a high level. If the level difference V2−V1 is the second level difference V2B−V1, which is smaller than the first level difference V2A−V1, the selection signal Se1 is at a low level.

Therefore, at the first level difference V2A−V1, into each gate of the serial switches P7 and P8, the high level is inputted, respectively. The serial switches P7 and P8 are turned off.

In the high-side switch 2b, the output transistor P1 is connected between the high-potential power line 4 and the output line 6 (connection point 7b). Also, between the high-potential power line 4 and the connection point 7a, the output transistor P2 is connected.

Therefore, the ON resistance of the high-side switch 2b becomes R(P1). Here, R(P1) is the ON resistance of the output transistor P1.

Also, if the level difference V2−V1 is the second level difference V2B−V1, which is smaller than the first level difference V2A−V1, the gates of the serial switches P7 and P8 fall to a low level. The serial switches P7 and P8 are turned on.

In the high-side switch 2b, between the high-potential power line 4 and the output line 6, the output transistor P1 is connected, and in parallel with the output transistor P1, the output transistor p5 and the serial switch P7 are connected.

Also, between the high-potential power line 4 and the connection point 7a, the output transistor P2 is connected, and in parallel with the output transistor P2, the output transistor P6 and the serial switch P8 are connected.

Therefore, the ON resistance of the high-side switch 2b is R(P1)×(R(P5)+(R(P7))/(R(P1)+R(P5)+R(P7)). Here, R(P1), R(P7), and R(P5) are ON resistances of the output transistors P1 and P5, and the serial switch P7, respectively.

As described above, the ON resistance of the high-side switch 2b when the level difference V2−V1 is the first level difference V2A−V1 is set larger than the ON resistance at the second level difference V2B−V1.

In the level shifter 1c, the ON resistance of the low-side switch 3b is R(N1). Here, R(N1) is the ON resistance of the input transistor N1.

Therefore, in the level shifter 1c, even if the potential V2 of the high-potential power line 4 is switched to potentials V2A and V2B, the transistor size ratio can be equivalently set to an optimal value with respect to the respective potentials.

Thus, according to the level shifter 1c, the propagation delay time tpd can be optimized to the plurality of power voltages.

In the level shifter 1c, the potential V2 of the high-potential power line 4 is switched to the potential V2A and V2B. However, the level difference V2−V1 may be changed by switching the high-level potential V1 of the input signals Ina and Inb.

Also, in the level shifter 1c, the configuration using the pair of output transistors P5 and P6 and the pair of serial switches P7 and P8 connected in parallel to the pair of output transistors P1 and P2 is illustrated. However, the arbitrary number of pairs of the output transistors and the serial switches may be used.

Also, in the level shifter 1c, the configuration which the ON resistance of the low-side switch 3b is not changed in accordance with the level difference V2−V1 is illustrated. However, the configuration may be such that the low-side switch 3b is replaced by the low-side switches 3 and 3a of the level shifters 1 and 1b and the ON resistance of the low-side switch is also changed in accordance with the level difference V2−V1.

### Fifth Embodiment

FIG. 6 is a circuit diagram illustrating the configuration of a level shifter according to a fifth embodiment.

As illustrated in FIG. 6, a level shifter 1d has a configuration in which the high-side switch 2b of the level shifter 1c illustrated in FIG. 5 is replaced by a high-side switch 2c. The low-side switch 3b is similar to that of the level shifter 1c. In the level shifter 1d, the ON resistance Rh of the high-side switch 2c is changed in accordance with the selection signal Se1.

The high-side switch 2c has a configuration in which the serial switches P7 and P8 of the high-side switch 2b are replaced by a pair of logical sum circuits (OR) 14 and 15. The output transistors P1 and P2 are similar to those of the high-side switch 2b.

The pair of output transistors P5 and P6 are connected in parallel to the output transistors P1 and P2, respectively. Into each gate of the pair of output transistors P5 and P6, a logical sum of the selection signal Se1 and each gate signal of the output transistors P1 and P2 is inputted.

In more detail, the source and drain of the output transistor P5 are connected to the high-potential power line 4 and the connection point 7b, respectively. The gate of the output transistor P5 is connected to an output of the OR 14. The OR 14 outputs a logical sum of the selection signal Se1 and the gate signal of the output transistor P1.

Similarly, the source and drain of the output transistor P6 are connected to the high-potential power line 4 and the connection point 7a, respectively. The gate of the output transistor P6 is connected to an output of the OR 15. The OR 15 outputs a logical sum of the selection signal Se1 and the gate signal of the output transistor P2.

As described above, if the level difference V2−V1 is the first level difference V2A−V1, the selection signal Se1 is at a high level. If the level difference V2−V1 is the second level difference V2B−V1, which is smaller than the first level difference V2A−V1, the selection signal Se1 is at a low level.

Therefore, at the first level difference V2A−V1, into each gate of the output transistors P5 and P6, the high level is inputted. The output transistors P5 and P6 are turned off.

In the high-side switch 2c, between the high-potential power line 4 and the output line 6, the output transistor P1 is connected. Also, between the high-potential power line 4 and the connection point 7a, the output transistor P2 is connected.

Therefore, the ON resistance of the high-side switch 2c becomes R(P1). Here, R(P1) is the ON resistance of the output transistor P1.

Also, if the level difference V2−V1 is the second level difference V2B−V1, which is smaller than the first level difference V2A−V1, each gate signal of the output transistors P1 and P2 is inputted into each gate of the output transistors P5 and P6, respectively. The output transistors P5 and P6 are turned on or off at the same time as the output transistors P1 and P2, respectively.

In the high-side switch 2c, between the high-potential power line 4 and the connection point 7b, the output transistor P1 is connected, and the output transistor P5 is connected in parallel to the output transistor P1.

Also, between the high-potential power line 4 and the connection point 7a, the output transistor P2 is connected, and the output transistor P6 is connected in parallel to the output transistor P2.

Therefore, the ON resistance of the high-side switch 2c is R(P1)×(R(P5)/(R(P1)+R(P5)). Here, R(P1) and R(P5) are ON resistances of the output transistors P1 and P5, respectively.

As described above, the ON resistance of the high-side switch 2c when the level difference V2−V1 is the first level difference V2A−V1 is set larger than the ON resistance at the second level difference V2B−V1.

In the level shifter 1d, the ON resistance of the low-side switch 3b is R(N1). Here, R(N1) is the ON resistance of the input transistor N1.

Therefore, in the level shifter 1d, even if the potential V2 of the high-potential power line 4 is switched to potentials V2A and V2B, the transistor size ratio can be equivalently set to an optimal value with respect to the respective potentials.

Thus, according to the level shifter 1d, the propagation delay time tpd can be optimized to the plurality of power voltages.

Also, in the high-side switch 2c, since there is no serial switch N7 or N8, the propagation delay time tpd can be shortened.

In the level shifter 1d, the potential V2 of the high-potential power line 4 is switched to the potential V2A and V2B. However, the level difference V2−V1 may be changed by switching the high-level potential V1 of the input signals Ina and Inb.

Also, in the level shifter 1d, the configuration using the pair of output transistors P5 and P6 and the pair of ORs 14 and 15 connected in parallel to the pair of output transistors P1 and P2 is illustrated. However, the arbitrary number of pairs of the output transistors and ORs may be used.

### Sixth Embodiment

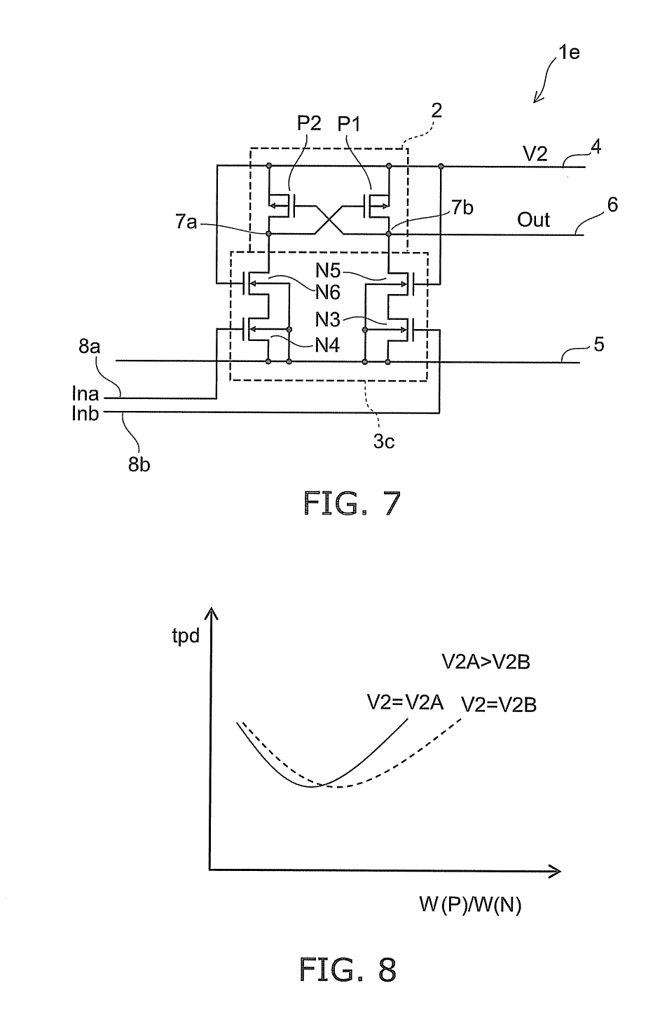

FIG. 7 is a circuit diagram illustrating the configuration of a level shifter according to a sixth embodiment.

As illustrated in FIG. 7, a level shifter 1e has a configuration in which the low-side switch 3 in the level shifter 1 illustrated in FIG. 1 is replaced by a low-side switch 3c. The high-side switch 2 is similar to that in the level shifter 1.

The low-side switch 3c has a configuration in which there is no pair of input transistors N1 and N2 of the low-side switch 3 and gates of the pair of serial transistors N5 and N6 are connected to the high-potential power line 4.

In more detail, the drain of the serial transistor N5 is connected to the drain of the output transistor P1 of the high-side switch 2 via the connection point 7b. The source of the serial transistor N5 is connected to the drain of the input transistor N3. The source of the input transistor N3 is connected to the low-potential power line 5. Into the gate of the input transistor N3, the input signal Inb is inputted. The gate of the serial transistor N5 is connected to the high-potential power line 4.

Similarly, the drain of the serial transistor N6 is connected to the drain of the output transistor P2 of the high-side switch 2. The source of the serial transistor N6 is connected to the drain of the input transistor N4. The source of the input transistor N4 is connected to the low-potential power line 5. Into the gate of the input transistor N4, the input signal Ina is inputted. The gate of the serial transistor N6 is connected to the high-potential power line 4.

The back gates of each NMOS such as the input transistors N3 and N4 and the serial transistors N5 and N6 are connected to the low-potential power line 5. Also, the back gates of each PMOS such as the output transistors P1 and P2 are connected to the high-potential power line 4.

The current supply capacity of the transistor is changed by a gate-source voltage. In the low-side switch 3c, the gates of the serial transistors N5 and N6 are connected to the high-potential power line 4. Thus, in accordance with the potential V2 of the high-potential power line 4, the current supply capacity and ON resistance of the serial transistors N5 and N6 are changed.

The ON resistance R(N5) of the serial transistor N5 is smaller when the level difference V2−V1 is the first level difference V2A−V1 than at the second level difference V2B−V1, which is smaller than the first level difference V2A−V1.

The ON resistance of the low-side switch 3c when the level difference V2−V1 is the first level difference V2A−V1 is set smaller than the ON resistance at the second level difference V2B−V1.

In the level shifter 1e, even if the potential V2 of the high-potential power line 4 is switched to potentials V2A and V2B, the transistor size ratio can be equivalently set to an optimal value with respect to the respective potentials.

Thus, according to the level shifter 1e, the propagation delay time tpd can be optimized to the plurality of power voltages.

Also, in the level shifter 1e, the configuration using the pair of input transistors N3 and N4 and the pair of serial transistors N5 and N6 is illustrated. However, the arbitrary number of pairs of input transistors and serial transistors may be used.

FIG. 8 is a characteristic diagram indicating dependency of the propagation delay time of the level shifter illustrated in FIG. 7 on the transistor size ratio.

In FIG. 8, the horizontal axis indicates the transistor size ratio W(P)/W(N), while the vertical axis indicates the propagation delay time tpd, and dependency in each of the cases of the potential V2 of the high-potential power line 4=V2A and V2B is schematically indicated. Each of the cases of the potential V2 of the high-potential power line 4=V2A and V2B corresponds to the case in which the level difference V2−V1 is the first level difference V2A−V1 and the case of the second level difference V2B−V1, respectively.

Here, the transistor size ratio W(P)/W(N) is a ratio between equivalent channel widths if the high-side switch 2 and the low-side switch 3c are constituted by a single transistor, respectively. The equivalent channel width W(P) of the high-side switch 2 is equal to the channel width W(P1) of the output transistor P1. The equivalent channel width W(N) of the low-side switch 3 is W(N3)×W(N5)/(W(N3)+N5)). Here, W(N3) and W(N5) are the channel width of the input transistor N3 and the channel width of the serial transistor N5, respectively.

In the level shifter 1e, in accordance with the potential V2 of the high-potential power line 4, the current supply capacities and the ON resistances of the serial transistors N5 and N6 of the low-side switch 3c are changed. Thus, as compared with the characteristics of the level shifter 1 illustrated in FIG. 2, dependency of the propagation delay time tpd on the transistor size ratio W(P)/W(N) when the potential V2 is changed is reduced.

Therefore, in the level shifter 1e, in accordance with the change of the level difference V2−V1, the transistor size ratio W(P)/W(N) can be equivalently set to an optimal value.

### Seventh Embodiment

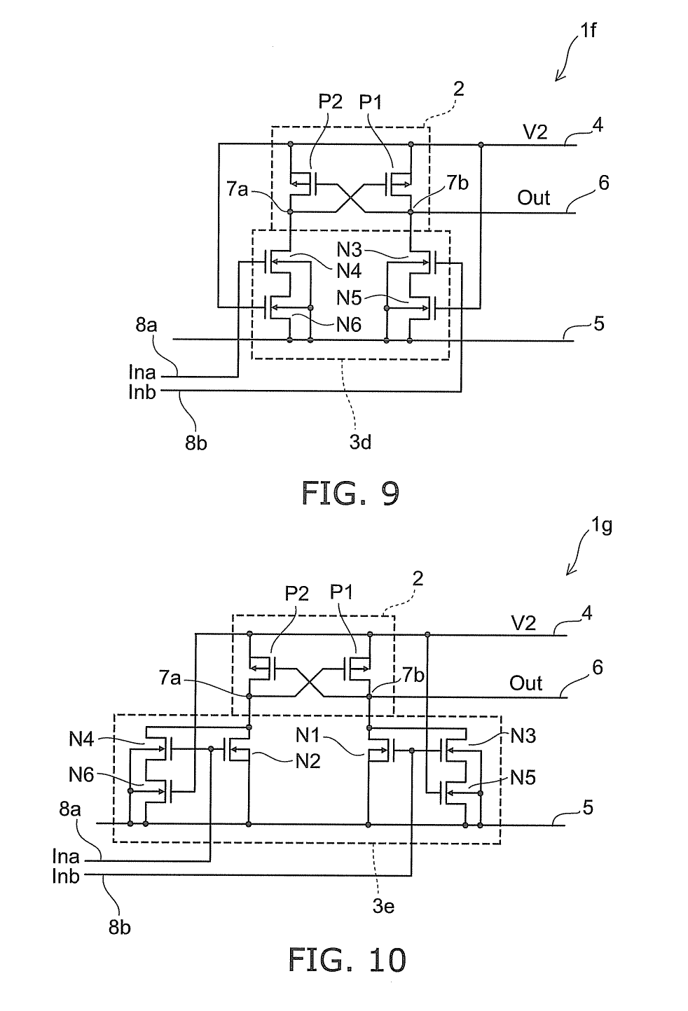

FIG. 9 is a circuit diagram illustrating the configuration of a level shifter according to a seventh embodiment.

As illustrated in FIG. 9, a level shifter 1f has a configuration in which the low-side switch 3c in the level shifter 1e illustrated in FIG. 7 is replaced by a low-side switch 3d. The high-side switch 2 is similar to that in the level shifter 1e.

In the level shifter 1e illustrated in FIG. 7, the pair of serial transistors N5 and N6 of the low-side switch 3c are connected in series to the high-voltage sides of the pair of input transistors N3 and N4. In the level shifter 1f illustrated in FIG. 9, the pair of serial transistors N5 and N6 of the low-side switch 3d are connected in series to the low-voltage sides of the pair of input transistors N3 and N4.

The back gate-source voltage of the input transistor N3 is equal to the source-drain voltage of the serial transistor N5. The source-drain voltage of the serial transistor N5 is changed by the voltage V2 of the high-potential power line 4.

The back gate-source voltage of the input transistor N3 is larger (the absolute value is smaller) when the level difference V2−V1 is the first level difference V2A−V1 than at the second level difference V2B−V1. As described above, the second level difference V2B−V1 is smaller than the first level difference V2A−V1. A substrate bias effect is smaller at the first level difference V2A−V1 than at the second level difference V2B−V1.

Therefore, the current supply capacity of the input transistor N3 is larger at the first level difference V2A−V1 than at the second level difference V2B−V1. Also, the ON resistance R(N3) is smaller at the first level difference V2A−V1 than at the second level difference V2B−V1.

As described above, in the low-side switch 3d, the ON resistance of the input transistor N3 and the ON resistance of the serial transistor N5 can be changed. The input transistor N3 and the serial transistor N5 have been described, but the same applies to the input transistor N4 and the serial transistor N6.

Thus, the ON resistance of the low-side switch 3d is set smaller when the level difference V2−V1 is the first level difference V2A−V1 than at the second level difference V2B−V1.

In the level shifter 1f, even if the potential V2 of the high-potential power line 4 is switched to potentials V2A and V2B, the transistor size ratio can be equivalently set to an optimal value with respect to the respective potentials.

Thus, according to the level shifter 1f, the propagation delay time tpd can be optimized to the plurality of power voltages.

Also, in the level shifter 1f, the configuration using the pair of input transistors N3 and N4 and the pair of serial transistors N5 and N6 is illustrated. However, the arbitrary number of pairs of input transistors and serial transistors may be used.

### Eighth Embodiment

FIG. 10 is a circuit diagram illustrating the configuration of a level shifter according to an eighth embodiment.

As illustrated in FIG. 10, a level shifter 1g has a configuration in which the low-side switch 3d of the level shifter if illustrated in FIG. 9 is replaced by a low-side switch 3e. The high-side switch 2 is similar to that in the level shifter 1f.

The low-side switch 3e has a configuration in which the pair of input transistors N1 and N2 are added to the low-side switch 3d. The pair of input transistors N1 and N2 are similar to the low-side switch 3 of the level shifter 1 illustrated in FIG. 1 and are connected between the high-side switch 2 and the low-potential power line 5, respectively.

The input transistor N1 is connected in parallel to the input transistor N3 and the serial transistor N5. Into the gate of the input transistor N1, the input signal Inb is inputted. The input transistor N2 is connected in parallel to the input transistor N4 and the serial transistor N6. Into the gate of the input transistor N2, the input signal Ina is inputted.

Since the ON resistance of the input transistor N1 is constant, a change characteristic of the ON resistance of the low-side switch 3e to the potential V2 of the high-potential power line 4 can be made different from the change characteristic of the ON resistance of the low-side switch 3e.

The level shifters 1 and 1a to 1g have been described concerning the configuration to convert the high level from the potential V1 of the input signals Ina and Inb to the potential V2 of the high-potential power line 4 based on the potential of the low-potential power line 5. However, the level shifter in which the low level is converted from the potential of the input signals Ina and Inb to the potential of the low-potential power line 5 may also be configured based on the potential of the low-potential power line 4.

### Ninth Embodiment

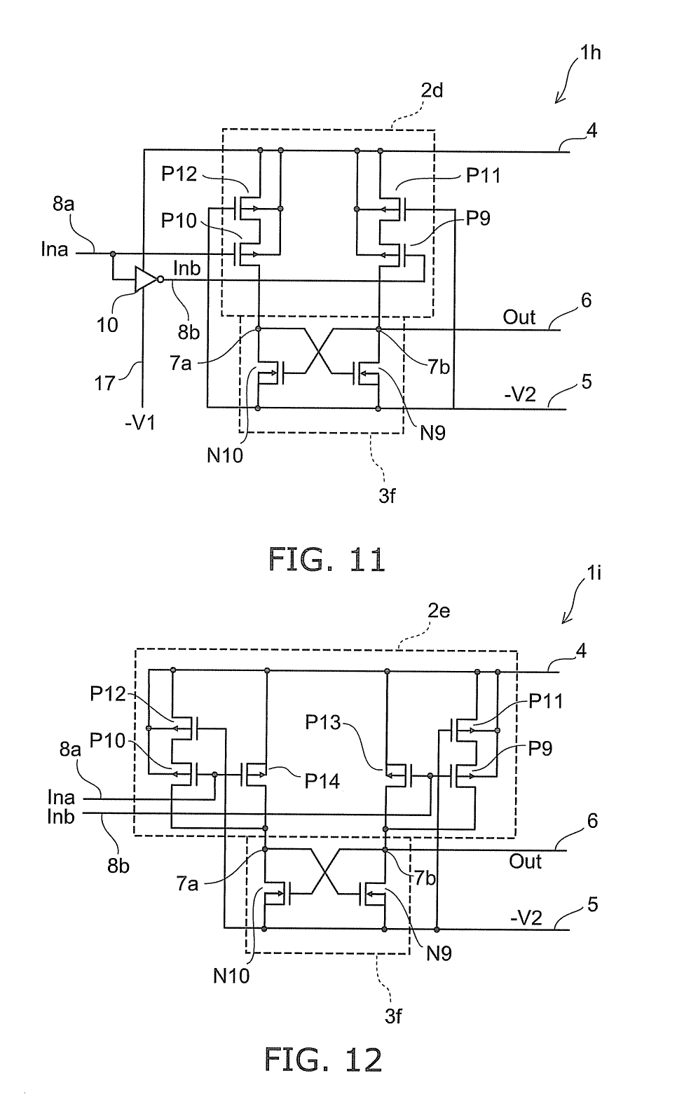

FIG. 11 is a circuit diagram illustrating the configuration of a level shifter according to a ninth embodiment.

As illustrated in FIG. 11, in a level shifter 1h, a high-side switch 2d and a low-side switch 3f are connected in series between the high-potential power line 4 and the low-potential power line 5. The output line 6 is connected to the connection point 7b between the high-side switch 2d and the low-side switch 3f.

The input lines 8a and 8b are connected to the high-side switch 2d, and the input signals Ina and Inb are inputted into the high-side switch 2d. Here, the input signals Ina and Inb are differential signals having a high level at a potential 0V and a low level at −V1 based on the potential of the high-potential power line 4. The input single Inb is a signal obtained by inverting the input signal Ina. The input signal Ina is inverted by the NOT 10 to which power with the potential −V1 is supplied from the power line 17.

The high-side switch 2d is tuned on or off in accordance with the input signals Ina and Inb. The low-side switch 3f is turned on or off in accordance with the state of the high-side switch 2d. The high-side switch 2d and the low-side switch 3f are turned on exclusively. Thus, the output line 6 is electrically connected to the high-potential power line 4 or the low-potential power line 5 in accordance with the input signals Ina and Inb.

An output signal Out of the output line 6 is a signal having a high level at a potential 0V and a low level at a potential −V2 based on the potential of the high-potential power line 4. Here, the potential −V2 is the potential of the low-potential power line 5 and is set to a value of the low-level potential −V1 or less of the input signals Ina and Inb. As for the potential −V2, there are two cases, that is, one case in which the potential −V2=−V2A and the other case in which the potential −V2=−V2B. However, −V2A≦≦V2B<0.

The level shifter 1h converts the input signals Ina and Inb with the low level at the potential −V1 to the output signal Out with the low level at the potential −V2.

Also, as will be described later, the ON resistance Rh of the high-side switch 2d between the high-potential power line 4 and the connection point 7b is set in accordance with the level difference V2−V1=V2A−V1, V2B−V1 between the input signals Ina and Inb and the output signal Out. The level difference V2−V1 is assumed to take an absolute value.

In the level shifter 1h, the ratio Rh/Rl between the ON resistance Rh of the high-side switch 2d between the high-potential power line 4 and the connection point 7b and the ON resistance Rl of the low-side switch 3f between the connection point 7b and the low-potential power line 5 is set in accordance with the level difference V2−V1.

The high-side switch 2d is constituted by a differential circuit of a pair of input transistors P9 and P10 and a pair of serial transistors P11 and P12. The input transistors P9 and P10 and the serial transistors P11 and P12 are constituted by PMOS, respectively.

The pair of input transistors P9 and P10 and the pair of serial transistors P11 and P12 are connected in series to the high-potential power line 4, respectively. Into each gate of the pair of input transistors P9 and P10, the input signals Inb and Ina are inputted, respectively. Each gate of the pair of serial transistors P11 and P12 is connected to the low-potential power line 5.

The current supply capacity and the ON resistance of the transistor are changed by the gate-source voltage. In the high-side switch 2d, the gates of the serial transistors P11 and P12 are connected to the low-potential power line 5. Thus, in accordance with the potential −V2 of the low-potential power line 5, the current supply capacity and the ON resistance of the serial transistors P11 and P12 are changed.

The ON resistance R(P11) of the serial transistor P11 is smaller when the level difference V2−V1 is the first level difference V2A−V1 than at the second level difference V2B−V1, which is smaller than the first level difference V2A−V1.

The ON resistance of the high-side switch 2d when the level difference V2−V1 is the first level difference V2A−V1 is set smaller than the ON resistance at the second level difference V2B−V1.

The low-side switch 3f is constituted by a differential circuit of a pair of output transistors N9 and N10. The pair of output transistors N9 and N10 are connected between the high-side switch 2d and the low-potential power line 5, respectively.

In more detail, a drain of the output transistor N9 is connected to a drain of the input transistor P9 of the high-side switch 2d via the connection point 7b. A source of the output transistor N9 is connected to the low-potential power line 5.

A drain of the output transistor N10 is connected to a drain of the input transistor P10 of the high-side switch 2d via the connection point 7a. A source of the output transistor N10 is connected to the low-potential power line 5.

A gate of the output transistor N9 is connected to the drain of the output transistor N10 and the drain of the input transistor P10 of the high-side switch 2d. A gate of the output transistor N10 is connected to the drain of the output transistor N9 and the drain of the input transistor P9 of the high-side switch 2d. The pair of output transistors N9 and N10 are cross-coupled.

The pair of output transistors N9 and N10 are differential circuits and exclusively turned on.

The output line 6 is connected to the gate of the output transistor N10 and the drain of the output transistor N9 via the connection point 7b.

If the output transistor N9 is ON and the output transistor N10 is OFF, the low-side switch 3f is ON. At this time, the output line 6 is electrically connected to the low-potential power line 5 via the connection point 7b. Also, if the output transistor N9 is OFF and the output transistor N10 is ON, the low-side switch 3f is OFF. At this time, the connection between the output line 6 and the low-potential power line 5 is shut off.

Subsequently, an operation of the level shifter 1h will be described.

When the input signal Inb is changed from a low level to a high level, the input transistor P9 of the high-side switch 2d is turned off. The high-side switch 2d between the high-potential power line 4 and the output line 6 is brought into an OFF state. At this time, the input transistor P10 is ON, and the gate of the output transistor N9 of the low-side switch 3f is at a high level. The output transistor N9 is turned on, and the low-side switch 3f is brought into an on state.

The output line 6 is electrically connected to the low-potential power line 5 via the connection point 7b and the output transistor N9. The output signal Out of the output line 6 falls from a high level to a low level and lowers to the potential −V2 of the low-potential power line 5. The larger the current supply capacity of the output transistor N9 of the low-side switch 3f is, the shorter the propagation delay time tpdl at the fall of the output signal Out becomes.

If the input signal Inb is changed from a high level to a low level, the input transistor P9 is turned on. The high-side switch 2d between the high-potential power line 4 and the output line 6 is brought into an ON state. The gate of the output transistor N10 of the low-side switch 3f rises to a high level. The output transistor N10 is turned on, and the gate of the output transistor N9 falls to a low level. The output transistor N9 is turned off. At this time, the input transistor P10 is OFF.

The output line 6 is electrically connected to the high-potential power line 4 via the input transistor P9 of the high-side switch 2d. The output signal Out of the output line 6 rises from a low level to a high level and rises to the potential 0V of the high-potential power line 4. The larger the current supply capacity of the high-side switch 2d is, the shorter the propagation delay time tpdh at the rise of the output signal Out becomes.

As described above, the propagation delay time tpd is an arithmetic average tpd=(tpdh+tpdl)/2 of the propagation delay times tpdh and tpdl.

Therefore, by setting a ratio between the current supply capacity of the high-side switch 2d and the current supply capacity of the low-side switch 3f at an optimal value, the propagation delay time tpd is minimized.

The optimal value relating to the current supply capacities of the high-side switch 2d and the low-side switch 3f depends on an element parameter of each transistor of the level shifter 1h. It also depends on the level difference V2−V1.

As described above, in the level shifter 1h, the ON resistance of the high-side switch 2d between the high-potential power line 4 and the connection point 7b is changed in accordance with the level difference V2−V1.

The ON resistance of the high-side switch 2d when the level difference V2−V1 is the first level difference V2A−V1 is set smaller than the ON resistance at the second level difference V2B−V1.

On the other hand, the ON resistance of the low-side switch 3f is constant.

Therefore, in the level shifter 1h, even if the potential −V2 of the low-potential power line 5 is switched to potentials −V2A and −V2B, the transistor size ratio can be equivalently set to an optimal value with respect to the respective potentials.

Thus, according to the level shifter 1h, the propagation delay time tpd can be optimized to the plurality of power voltages.

### Tenth Embodiment

FIG. 12 is a circuit diagram illustrating the configuration of a level shifter according to a tenth embodiment.

As illustrated in FIG. 12, a level shifter 1i has a configuration in which the high-side switch 2d in the level shifter 1h illustrated in FIG. 11 is replaced by a high-side switch 2e. The low-side switch 3f is similar to that in the level shifter 1h.

The high-side switch 2e has a configuration in which a pair of input transistors P13 and P14 are added to the high-side switch 2d. The pair of input transistors P13 and P14 are connected to the high-potential power line 4, respectively.

The input transistor P13 is connected in parallel to the input transistor P9 and the serial transistor P11. Into a gate of the input transistor P13, the input signal Inb is inputted. The input transistor P14 is connected in parallel to the input transistor 10 and the serial transistor P12. Into a gate of the input transistor P14, the input signal Ina is inputted.

In the level shifter 1i, even if the potential −V2 of the low-potential power line 5 is switched to potentials −V2A and −V2B, the transistor size ratio can be equivalently set to an optimal value with respect to the respective potentials.

Thus, according to the level shifter 1i, the propagation delay time tpd can be optimized to the plurality of power voltages.

Since the ON resistance of the input transistor P13 is constant, the change characteristic of the ON resistance of the high-side switch 2e to the potential −V2 of the low-potential power line 5 can be made different from the change characteristic of the ON resistance of the high-side switch 2d.

Also, in the level shifters 1h and 1i, the configuration using the pair of input transistors P9 and P10 and the pair of serial transistors P11 and P12 is illustrated. However, the arbitrary number of pairs of the input transistors and the serial transistors may be used.

Also, in the level shifters 1h and 1i, the serial transistors P11 and P12 are connected in series on the high-potential sides of the pair of input transistors P9 and P10. However, the serial transistors P11 and P12 may be connected in series on the low-potential side.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A level shifter comprising:
a high-side switch connected between a high-potential power supply and a connection point and turned on in accordance with an input signal; and
a low-side switch connected between the connection point and a low-potential power supply and turned on in accordance with an input signal,
a ratio between ON resistance of the high-side switch and ON resistance of the low-side switch being set in accordance with a signal difference between an output signal outputted to the connection point and the input signal.

2. The shifter according to claim 1, wherein
the input signal is inputted to the low-side switch, and the ratio between the ON resistance of the high-side switch and the ON resistance of the low-side switch is set so as to become larger in accordance with an increase of the signal difference.

3. The shifter according to claim 1, wherein
the low-side switch includes an input transistor connected between the high-side switch and the low-potential power supply and to which the input signal is inputted;
the high-side switch includes an output transistor that is switched to on or off in accordance with a state of the input transistor; and
a ratio between the ON resistance of the high-side switch and the ON resistance of the low-side switch when the signal difference is a first level difference is set larger than a ratio between the ON resistance of the high-side switch and the ON resistance of the low-side switch at a second level difference, which is smaller than the first level difference.

4. The shifter according to claim 3, wherein
the high-side switch is connected in series to the output transistor and further includes a p-type channel MOSFET to which the input signal is inputted.

5. The shifter according to claim 3, wherein
the low-side switch is connected in series to the input transistor and further includes a serial transistor that is turned on at the first level difference and turned off at the second level difference.

6. The shifter according to claim 5, wherein
a high level is inputted to a gate of the serial transistor at the first level difference, and a low level is inputted to a gate of the serial transistor at the second level difference.

7. The shifter according to claim 3, wherein
the low-side switch further includes a serial transistor connected in series to the input transistor; and
an ON resistance of the serial transistor at the first level difference is set smaller than an ON resistance of the serial transistor at the second level difference.

8. The shifter according to claim 7, wherein
a gate of the serial transistor is connected to the high-potential power supply.

9. The shifter according to claim 8, wherein
each back gate of the input transistor and the serial transistor is connected to the low-potential power supply.

10. The shifter according to claim 7, wherein
the high-side switch is connected in series to the output transistor and further includes a p-type channel MOSFET to which the input signal is inputted.

11. The shifter according to claim 3, wherein
the low-side switch further includes a logical product circuit connected to a gate of the input transistor, and
an input signal is inputted to the gate of the input transistor at the first level difference and a low level is inputted to the gate of the input transistor at the second level difference.

12. The shifter according to claim 3, wherein
the high-side switch is connected in series to the output transistor and further includes a serial switch that is turned off at the first level difference and turned on at the second level difference.

13. The shifter according to claim 3, wherein
the high-side switch further includes a logical sum circuit connected to a gate of the output transistor; and
a high level is inputted to the gate of the output transistor at the first level difference, and the high level or a low level is inputted to the gate of the output transistor according to a state of the low-side switch at the second level difference.

14. The shifter according to claim 3, wherein
the high-side switch is formed of a differential circuit that are cross-couple connected.

15. The shifter according to claim 3, wherein
the low-side switch is formed of a differential circuit.

16. The shifter according to claim 1, wherein
the input signal is inputted to the high-side switch, and the ratio between the ON resistance of the high-side switch and the ON resistance of the low-side switch is set so as to become smaller in accordance with an increase of the signal difference.

17. The shifter according to claim 16, wherein
the high-side switch includes an input transistor to which the input signal is inputted,
the low-side switch includes an output transistor connected between the high-side switch and the low-potential power supply and switched to on or off in accordance with a state of the high-side switch, and
a ratio between the ON resistance of the high-side switch and the ON resistance of the low-side switch when the signal difference is a first level difference is set smaller than a ratio between the ON resistance of the high-side switch and the ON resistance of the low-side switch at a second level difference, which is lower than the first level difference.

18. The shifter according to claim 17, wherein
the high-side switch further includes a serial transistor connected in series to the input transistor; and
an ON resistance of the serial transistor at the first level difference is set smaller than an ON resistance of the serial transistor at the second level difference.

19. The shifter according to claim 18, wherein
a gate of the serial transistor is connected to the low-potential power supply.

20. The shifter according to claim 19, wherein
each back gate of the input transistor and the serial transistor is connected to the high-potential power supply.
